(19) United States
(12) Patent Application Publication
(10) Pub. No.: US 2012/0100309 A1
(43) Pub. Date: Apr. 26, 2012

(54) PLASMA TREATMENT APPARATUS AND PLASMA CVD APPARATUS

(75) Inventors: Hidekazu MIYAIRI, Atsugi (JP); Yoichiro NUMASAWA, Tokyo (JP); Takayuki INOUE, Isehara (JP); Kojiro TAKAHASHI, Isehara (JP); Mitsuhiro ICHIJO, Zama (JP)

(73) Assignee: SEMICONDUCTOR ENERGY LABORATORY CO., LTD., Atsugi-shi (JP)

(21) Appl. No.: 13/273,258

(22) Filed: Oct. 14, 2011

(30) Foreign Application Priority Data
Oct. 26, 2010 (JP) 2010-239266

(51) Int. Cl. C23C 16/50; C23C 16/52; C23C 16/455

(52) U.S. Cl. 427/569; 118/723 E; 118/712

(57) ABSTRACT

A plasma treatment apparatus includes a treatment chamber covered with a chamber wall, where an upper electrode faces a lower electrode; and a line chamber separated from the treatment chamber by the upper electrode and an insulator, covered with the chamber wall, and connected to a first gas diffusion chamber between a dispersion plate and a shower plate. The first gas diffusion chamber is connected to a second gas diffusion chamber between the dispersion plate and the upper electrode. The second gas diffusion chamber is connected to a first gas pipe in the upper electrode. The upper electrode and the chamber wall are provided on the same axis. The dispersion plate includes a center portion with no gas hole and a peripheral portion with plural gas holes. The center portion faces a gas introduction port of the first gas pipe, connected to an electrode plane of the upper electrode.

### BACKGROUND OF THE INVENTION

1. Field of the Invention

The present invention relates to a plasma treatment apparatus and a plasma CVD apparatus.

2. Description of the Related Art

In recent years, semiconductor devices have been indispensable to human life. The semiconductor device herein refers to a device including at least one transistor, and various electronic devices are included in the category of the semiconductor device.

An element such as a transistor included in a semiconductor device is formed using a thin film. Plasma treatment is necessary to form such a thin film. Note that a plasma CVD method and the like are also included in plasma treatment here. For example, when a thin film transistor is formed using a glass substrate, a gate insulating film is formed by a plasma CVD method, so that a dense film can be formed at a low temperature.

In this manner, a plasma treatment is used when an element such as a transistor included in a semiconductor device is manufactured; therefore, technological development of a plasma treatment apparatus has also been promoted in a variety of ways (e.g., Patent Document 1).

### Reference

Patent Document 1 Japanese Published Patent Application No. H11-297496

### SUMMARY OF THE INVENTION

As one of capabilities required for a plasma treatment apparatus, the uniformity of plasma is given. In order to improve the uniformity of plasma, time average of electric field intensity between an upper electrode and a lower electrode and the distribution of an introduced gas are preferably made uniform. Note that “time average” means an average value of electric field intensity in one period.

An embodiment of the present invention is to provide a plasma treatment apparatus by which electric field intensity and distribution of an introduced gas can be made uniform.

A plasma treatment apparatus according to an embodiment of the present invention includes a structure in which an upper electrode and a chamber wall which covers the upper electrode are on the same axis and a gas introduced through a gas pipe in the upper electrode is introduced into a treatment chamber through a dispersion plate and a shower plate. The dispersion plate includes a center portion of the dispersion plate which faces the gas pipe in the upper electrode and which is provided with no gas hole and a peripheral portion of the dispersion plate which surrounds the center portion of the dispersion plate and which is provided with a plurality of gas holes.

A plasma treatment apparatus according to an embodiment of the present invention includes a treatment chamber in which an electrode plane of an upper electrode and an electrode plane of a lower electrode face each other and which is covered with a chamber wall; and a line chamber which is separated from the treatment chamber by the upper electrode and an insulator and which is covered with a chamber wall which is the same as the chamber wall. The treatment chamber is connected to a first gas diffusion chamber provided between a dispersion plate and a shower plate. The first gas diffusion chamber is connected to a second gas diffusion chamber provided between the dispersion plate and the electrode plane of the upper electrode. The second gas diffusion chamber is connected to a first gas pipe in the upper electrode. The first gas pipe in the upper electrode is connected to a second gas pipe. The second gas pipe is connected to a process gas supply source. The line chamber includes a gas introduction port connected to an inert gas supply source, and the upper electrode and the chamber wall which are provided on the same axis. The dispersion plate includes a center portion of the dispersion plate, which is provided with no gas hole; and a peripheral portion of the dispersion plate, which is provided with a plurality of gas holes. The center portion of the dispersion plate faces a gas introduction port of the first gas pipe in the upper electrode, which is connected to the electrode plane of the upper electrode. The peripheral portion of the dispersion plate surrounds the center portion of the dispersion plate.

In the above structure, the shower plate is provided with a plurality of gas holes, and the number of gas holes of the shower plate is preferably larger than the number of gas holes of the dispersion plate. Alternatively, in the above structure, the shower plate is provided with a plurality of gas holes, and the total area of the gas holes in a main surface of the shower plate is preferably larger than the total area of the gas holes in a main surface of the dispersion plate. This is because a gas can be uniformly dispersed in the first gas diffusion chamber.

In the above structure, a thermometer is connected to the upper electrode, and a connection portion of the thermometer in the upper electrode is preferably symmetrical to a gas introduction port of the first gas pipe in the upper electrode with respect to the center point of an electrode plane of the upper electrode. This is because the uniformity of an electric field from the upper electrode can be increased. Alternatively, in the above structure, the upper electrode is preferably provided with a path of a cooling medium which bypasses the vicinity of the gas introduction port of the first gas pipe in the upper electrode. As the cooling medium, for example, water, oil, or the like can be used. Alternatively, the plasma treatment apparatus may be connectable to an exhaust system.

A plasma treatment apparatus according to an embodiment of the present invention includes a first electrode; a path in the first electrode; a pipe connected to a first port of the path; a first plate under the first electrode wherein the first plate includes a first portion including no hole and a second portion including a plurality of holes, and the first portion overlaps with a second port of the path; a second electrode under the first electrode with the first plate interposed between the first electrode and the second electrode; and a wall surrounding the first electrode and the first plate, wherein the wall and the first electrode are provided on the same axis. The plasma treatment apparatus may further include a second plate under the first plate, the second plate including a plurality of holes, wherein the number of holes of the second plate is larger than the number of holes of the first plate. Alternatively, the plasma treatment apparatus may include a second plate under the first plate, the second plate including a plurality of holes, wherein the total area of holes of the second plate is larger than the total area of holes of the first plate. Alternatively, the plasma treatment apparatus in which the first electrode includes a part capable of being connected to a thermometer, and in which the part is provided to be symmetrical to the first port with respect to a center point of a surface of the first electrode may be provided. Alternatively, the plasma treatment apparatus in which the first electrode includes a second path capable of flowing a cooling medium, and in which the second path bypasses a vicinity of the first port may be provided. Alternatively, the plasma treatment apparatus in which the plasma treatment apparatus is connectable to an exhaust system may be provided. Alternatively, the plasma treatment apparatus may further include an insulator interposed between the wall and a side surface of the first electrode. Alternatively, the plasma treatment apparatus in which the first plate has a disk shape may be provided. Alternatively, the plasma treatment apparatus in which the plasma treatment apparatus is used for film formation may be provided. Alternatively, the plasma treatment apparatus in which a chamber covered with the wall, a surface of the first electrode, and an insulator is connected to an inert gas supply source may be provided.

A plasma treatment apparatus having the above structure is, for example, a plasma CVD apparatus.

It is possible to provide a plasma treatment apparatus in which the intensity of an electric field from an upper electrode and the distribution of an introduced gas can be made uniform.

### BRIEF DESCRIPTION OF THE DRAWINGS

FIGS. 1A and 1B are schematic diagrams of a plasma treatment apparatus according to one embodiment of the present invention.

FIG. 2 is a schematic diagram of a dispersion plate of a plasma treatment apparatus according to one embodiment of the present invention.

FIG. 3 is a schematic diagram of an electrode plane of an upper electrode of a plasma treatment apparatus according to one embodiment of the present invention.

FIGS. 4A to 4C are conceptual graphs each showing distribution of electric field intensity or the like of the plasma treatment apparatus in FIGS. 1A and 1B.

### DETAILED DESCRIPTION OF THE INVENTION

Hereinafter, embodiments of the present invention will be described in detail with reference to the accompanying drawings. However, the present invention is not limited to the following description and it is easily understood by those skilled in the art that the mode and details can be variously changed without departing from the scope and spirit of the present invention. Accordingly, the present invention should not be construed as being limited to the description of the embodiments below.

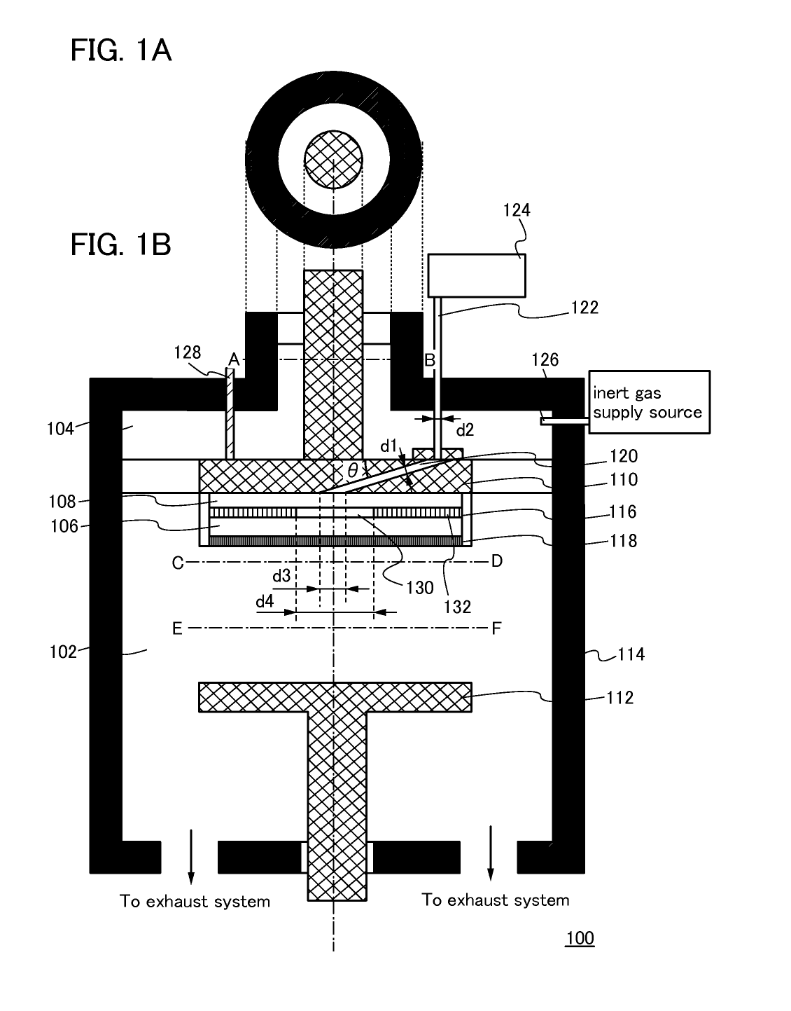

FIGS. 1A and 1B are schematic diagrams of a plasma treatment apparatus according to one embodiment of the present invention. FIG. 1B is a cross-sectional view of a main structure of a plasma treatment apparatus 100 as a whole and FIG. 1A is a cross-sectional view along line A-B in FIG. 1B.

The plasma treatment apparatus 100 illustrated in FIGS. 1A and 1B includes a treatment chamber 102 and a line chamber 104. The treatment chamber 102 is covered with a chamber wall 114, and in the treatment chamber 102, an upper electrode 110 and a lower electrode 112 are provided so that their electrode planes face each other. The line chamber 104 is covered with the chamber wall 114 and is separated from the treatment chamber 102 by the upper electrode 110 and an insulator (a portion which is not shaded and is between an electrode plane of the upper electrode 110 and the chamber wall 114).

The treatment chamber 102 is connected to a first gas diffusion chamber 106 provided between a dispersion plate 116 and a shower plate 118. The first gas diffusion chamber 106 is connected to a second gas diffusion chamber 108 provided between the dispersion plate 116 and the electrode plane of the upper electrode 110. The second gas diffusion chamber 108 is connected to a first gas pipe 120 in the upper electrode 110. The first gas pipe 120 in the upper electrode 110 is connected to a second gas pipe 122. The second gas pipe 122 is connected to a process gas supply source 124.

The line chamber 104 includes a gas introduction port 126 connected to an inert gas supply source, and the upper electrode 110 and the chamber wall 114 which are provided on the same axis. The line chamber 104 is preferably set to an inert gas atmosphere at a positive pressure.

Note that in this specification, an “atmosphere at a positive pressure” preferably means a pressure higher than the atmospheric pressure; however, it is not limited thereto. It is acceptable as long as the atmosphere is at a pressure higher than the pressure in the treatment chamber.

When the inside of the line chamber 104 is set to an inert gas atmosphere at a positive pressure, oxidation or the like of components of the line chamber 104 is prevented, so that the frequency of maintenance can be reduced and mean time between failures (MTBF) can be increased.

Further, since in the plasma treatment apparatus illustrated in FIGS. 1A and 1B, the upper electrode 110 and the chamber wall 114 are on the same axis, a path for an introduced inert gas is not blocked. Therefore, in a line portion of the upper electrode 110, the uniformity of temperature distribution at the same height is increased and propagation of power on a surface of the line portion of the upper electrode in the case where power supplied to the upper electrode 110 has a high frequency can be stabilized. Accordingly, when the upper electrode 110 and the chamber wall 114 are on the same axis, impedance can be reduced and transmission efficiency can be increased. Moreover, the uniformity of the distribution of an electric field in the upper electrode 110 can be increased.

Here, when the diameter of the line portion of the upper electrode 110 is d, the diameter of the inside of the chamber wall 114 is D, and the dielectric constant of the atmosphere in the line chamber 104 is ε, impedance Z is expressed by Formula 1.

$$Z = \frac{138}{\sqrt{ɛ}} {log}_{10} \frac{D}{d} \qquad [ Formula 1 ]$$

According to the above Formula 1, when the dielectric constant ε is increased, the impedance Z can be reduced. Since a gas introduced into the line chamber 104 can be selected as appropriate, the impedance Z can be reduced by selecting a gas whose dielectric constant ε is high. For example, when the atmosphere of the line chamber 104 is a nitrogen atmosphere, the dielectric constant ε is about 5.47 at a temperature of 20° C. in the atmosphere of the line chamber 104. Alternatively, when the atmosphere of the line chamber 104 is an argon atmosphere, the dielectric constant ε is about 5.17 at a temperature of 20° C. in the atmosphere of the line chamber 104.

In addition, when the inside of the line chamber 104 is set to an inert gas atmosphere at a positive pressure, heat of components of the line chamber 104 can be removed; therefore, for example, even in the case where the upper electrode 110 is provided with a heater, the upper electrode 110 can be prevented from overheating. Note that it is preferable that a thermometer 128 be connected to the upper electrode 110 as illustrated in FIG. 1B.

Further, when the inside of the line chamber 104 is set to an inert gas atmosphere at a positive pressure, entry of atmospheric components to the treatment chamber 102 can be suppressed even in the case where leakage occurs in the chamber wall 114.

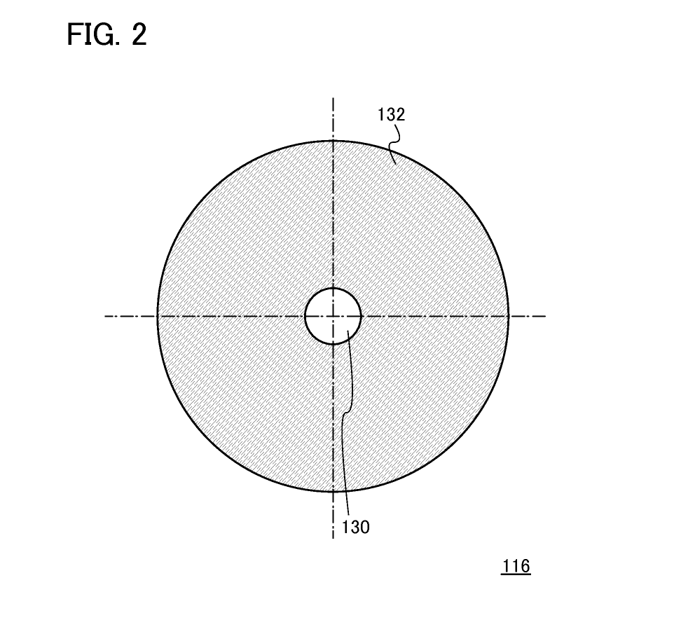

FIG. 2 is a schematic diagram of a main surface of the dispersion plate 116. The dispersion plate 116 illustrated in FIG. 2 includes a center portion 130 of the dispersion plate and a peripheral portion 132 of the dispersion plate. The center portion 130 of the dispersion plate is provided with no gas hole and is provided so as to face a gas introduction port of the first gas pipe 120 in the upper electrode 110, the first gas pipe connected to the electrode plane of the upper electrode 110. The peripheral portion 132 of the dispersion plate is provided with a plurality of gas holes.

Note that the shower plate 118 is provided with a plurality of gas holes, and the number of gas holes of the shower plate 118 is preferably larger than the number of gas holes of the dispersion plate 116. Alternatively, the shower plate 118 is provided with a plurality of gas holes, and the total area of the gas holes of the shower plate 118 is preferably larger than the total area of the gas holes of the dispersion plate 116. This is because a gas can be diffused uniformly.

As described above, the center portion 130 of the dispersion plate 116 is provided with no gas hole; therefore, it is possible to prevent introduction of a gas introduced from the gas introduction port of the first gas pipe 120 into the first gas diffusion chamber 106 without sufficient diffusion and to increase the uniformity of a gas introduced into the treatment chamber 102.

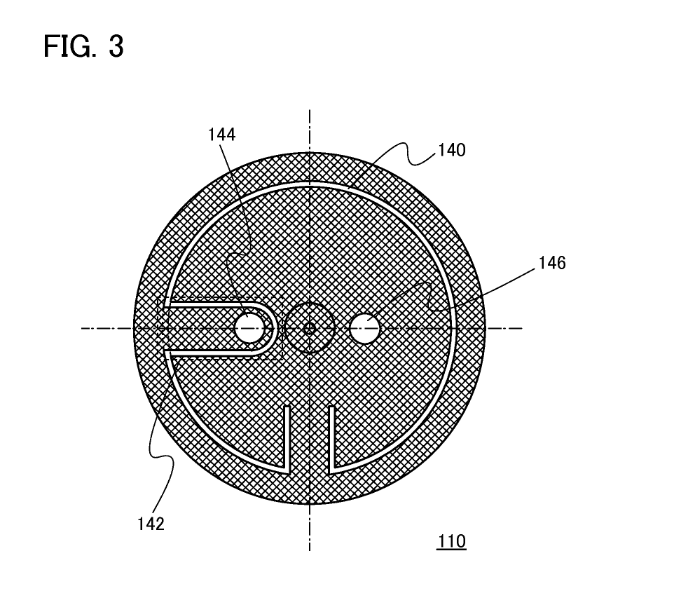

FIG. 3 illustrates an example of the electrode plane of the upper electrode 110. Note that FIG. 3 is a diagram of the electrode plane of the upper electrode 110, which is seen from the opposite side of the lower electrode 112. The upper electrode 110 illustrated in FIG. 3 is provided with a gas introduction port 144 of the first gas pipe 120, a connection portion 146 of the thermometer, and a cooling medium path 140, and the cooling medium path 140 includes a bypass portion 142 in the vicinity of the gas introduction port 144 of the first gas pipe 120.

The connection portion 146 of the thermometer is preferably located so as to be symmetrical to the gas introduction port 144 of the first gas pipe 120 in the upper electrode 110 with respect to the center point of the electrode plane of the upper electrode 110. This is because the thermometer can be connected to the upper electrode 110 without reducing the uniformity of an electric field from the upper electrode 110.

The bypass portion 142 is preferably provided in the vicinity of the gas introduction port 144 of the first gas pipe 120. As the cooling medium, for example, water, oil, or the like can be used.

Note that the cooling medium path 140 is not limited to the mode illustrated in FIG. 3. Therefore, the bypass portion 142 is not necessarily provided.

The diameter d1 of a cross section of a main portion of the first gas pipe 120 and the diameter d2 of a cross section of a main portion of the second gas pipe 122 may be set to a length with which electric discharge is not caused in the first gas pipe 120 or the second gas pipe 122 when power is supplied to the upper electrode 110. In addition, d1 and d2 are preferably substantially the same.

When an angle formed between the electrode plane of the upper electrode 110 and the first gas pipe 120 is θ, the diameter d3 of the gas introduction port of the first gas pipe 120 is represented by d3=d1/sin θ. Note that the diameter of the first gas pipe 120 may be enlarged in the gas introduction port. Note that the diameter d3 of the gas introduction port of the first gas pipe 120 is also set to a length with which electric discharge is not caused.

The diameter d4 of the center portion 130 of the dispersion plate is preferably larger than the diameter d3 of the gas introduction port of the first gas pipe 120. This is because a gas introduced from the gas introduction port of the first gas pipe 120 is prevented from being introduced into the first gas diffusion chamber 106 without diffusion.

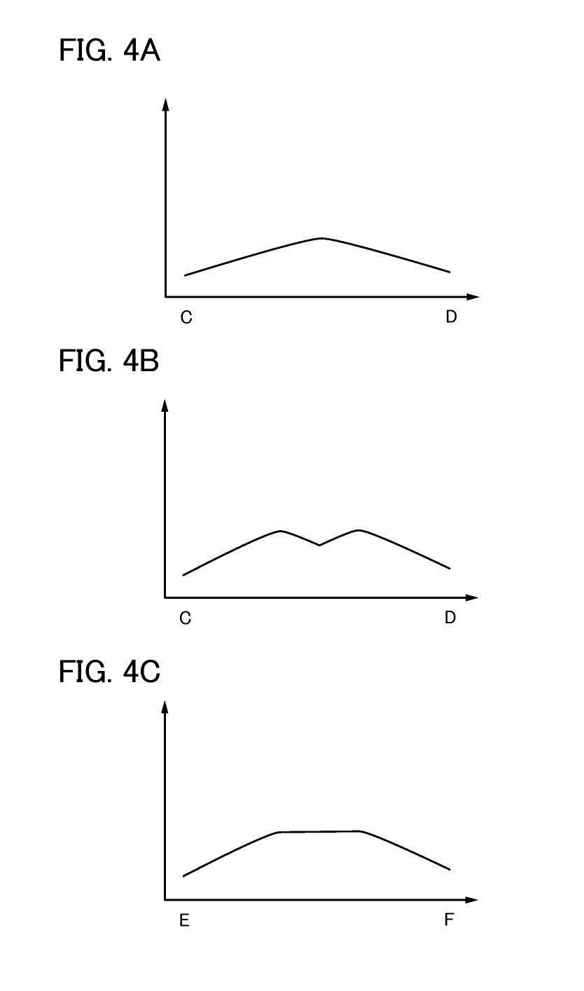

FIGS. 4A to 4C are conceptual graphs of distribution of electric field intensity along line C-D (FIG. 4A), distribution of a process gas along line C-D (FIG. 4B), and distribution of a reactive substance along line E-F (FIG. 4C), when a process gas is introduced into the treatment chamber 102 in the plasma treatment apparatus 100 in FIGS. 1A and 1B and voltage is applied to the upper electrode 110 and the lower electrode 112.

As shown in FIG. 4A, the electric field intensity has a peak in a position overlapped with the center portions of the upper electrode 110 and the lower electrode 112; however, the gradient is gentle because the uniformity of the electric field intensity is high in the plasma treatment apparatus 100 illustrated in FIGS. 1A and 1B. As shown in FIG. 4B, the distribution of the process gas has two peaks in a position other than a position overlapped with the center portion 130 of the dispersion plate.

It can be considered from the distribution of the electric field intensity shown in FIG. 4A and the distribution of the process gas shown in FIG. 4B that the reaction substance (ionized material substance) is distributed as shown in FIG. 4C. In the case where the reaction substance (ionized material substance) is distributed as shown in FIG. 4C, for example, when film formation is performed over a substrate by a plasma CVD method using the plasma treatment apparatus 100, variation in the film thickness in a substrate plane can be reduced and the uniformity in the film quality can be increased. Alternatively, in a case other than the case where film formation is performed, plasma treatment with high uniformity can be performed on a substrate.

Note that the plasma treatment apparatus which is an embodiment of the present invention is especially effective when plasma treatment is performed under a pressure of greater than or equal to 2000 Pa and less than or equal to 100000 Pa, preferably greater than or equal to 4000 Pa and less than or equal to 50000 Pa.

This application is based on Japanese Patent Application serial no. 2010-239266 filed with Japan Patent Office on Oct. 26, 2010, the entire contents of which are hereby incorporated by reference.

What is claimed is:

1. A plasma treatment apparatus comprising:
a treatment chamber covered with a first part of a chamber wall, wherein an electrode plane of an upper electrode and an electrode plane of a lower electrode face each other;
a line chamber covered with a second part of the chamber wall and separated from the treatment chamber by the upper electrode and an insulator;
a first gas diffusion chamber between a dispersion plate and a shower plate, wherein the first gas diffusion chamber is connected to the treatment chamber;
a second gas diffusion chamber between the dispersion plate and the electrode plane of the upper electrode, wherein the second gas diffusion chamber is connected to the first gas diffusion chamber and a first gas pipe in the upper electrode;
wherein the first gas pipe in the upper electrode is connected to a second gas pipe,
wherein the second gas pipe is connected to a process gas supply source,
wherein the line chamber includes a gas introduction port connected to an inert gas supply source, and the upper electrode and the chamber wall which are provided on a same axis, and
wherein the dispersion plate includes:
a center portion that faces a gas introduction port of the first gas pipe in the upper electrode and is provided with no gas hole, wherein the gas introduction port of the first gas pipe in the upper electrode is connected to the electrode plane of the upper electrode; and
a peripheral portion that surrounds the center portion and is provided with a plurality of gas holes.

2. The plasma treatment apparatus according to claim 1,
wherein the shower plate comprises a plurality of gas holes, and
wherein the number of the gas holes of the shower plate is larger than the number of the gas holes of the dispersion plate.

3. The plasma treatment apparatus according to claim 1,
wherein the shower plate comprises a plurality of gas holes, and
wherein a total area of the gas holes in a surface of the shower plate is larger than a total area of the gas holes in a surface of the dispersion plate.

4. The plasma treatment apparatus according to claim 1, further comprising:
a thermometer connected to the upper electrode,
wherein a connection portion of the thermometer in the upper electrode is symmetrical to a gas introduction port of the first gas pipe in the upper electrode with respect to a center point of the electrode plane of the upper electrode.

5. The plasma treatment apparatus according to claim 1, wherein the upper electrode comprises a path of a cooling medium, the path bypassing a vicinity of a gas introduction port of the first gas pipe in the upper electrode.

6. A plasma CVD apparatus that is the plasma treatment apparatus according to claim 1.

7. The plasma treatment apparatus according to claim 1, wherein the plasma treatment apparatus is connectable to an exhaust system.

8. A plasma treatment apparatus comprising:
a first electrode;
a path in the first electrode;
a pipe connected to a first port of the path;
a first plate under the first electrode, wherein the first plate comprises a first portion including no hole and a second portion including a plurality of holes, and the first portion overlaps with a second port of the path;
a second electrode under the first electrode with the first plate interposed between the first electrode and the second electrode; and
a wall surrounding the first electrode and the first plate,
wherein the wall and the first electrode are provided on a same axis.

9. The plasma treatment apparatus according to claim 8, further comprising:
a second plate under the first plate, the second plate comprising a plurality of holes,
wherein the number of the holes of the second plate is larger than the number of the holes of the first plate.

10. The plasma treatment apparatus according to claim 8, further comprising:
a second plate under the first plate, the second plate comprising a plurality of holes,
wherein a total area of the holes of the second plate is larger than a total area of the holes of the first plate.

11. The plasma treatment apparatus according to claim 8,
wherein the first electrode comprises a part capable of being connected to a thermometer, and
wherein the part is provided to be symmetrical to the first port with respect to a center point of a surface of the first electrode.

12. The plasma treatment apparatus according to claim 8,
wherein the first electrode comprises a second path capable of flowing a cooling medium, and
wherein the second path bypasses a vicinity of the first port.

13. A plasma CVD apparatus that is the plasma treatment apparatus according to claim 8.

14. The plasma treatment apparatus according to claim 8, wherein the plasma treatment apparatus is connectable to an exhaust system.

15. The plasma treatment apparatus according to claim 8, further comprising:
an insulator interposed between the wall and a side surface of the first electrode.

16. The plasma treatment apparatus according to claim 8, wherein the first plate has a disk shape.

17. The plasma treatment apparatus according to claim 8, wherein the plasma treatment apparatus is used for film formation.

18. The plasma treatment apparatus according to claim 8, wherein a chamber covered with the wall, a surface of the first electrode, and an insulator is connected to an inert gas supply source.

19. A manufacturing method for forming a film in a plasma treatment apparatus,
wherein the plasma treatment apparatus comprises:
a treatment chamber covered with a first part of a chamber wall, wherein an electrode plane of an upper electrode and an electrode plane of a lower electrode face each other;
a line chamber covered with a second part of the chamber wall and separated from the treatment chamber by the upper electrode and an insulator;
a first gas diffusion chamber between a dispersion plate and a shower plate, wherein the first gas diffusion chamber is connected to the treatment chamber;
a second gas diffusion chamber between the dispersion plate and the electrode plane of the upper electrode, wherein the second gas diffusion chamber is connected to the first gas diffusion chamber and a first gas pipe in the upper electrode;
wherein the first gas pipe in the upper electrode is connected to a second gas pipe,
wherein the second gas pipe is connected to a process gas supply source,
wherein the line chamber includes a gas introduction port connected to an inert gas supply source, and the upper electrode and the chamber wall which are provided on a same axis, and
wherein the dispersion plate includes:
a center portion that faces a gas introduction port of the first gas pipe in the upper electrode and is provided with no gas hole, wherein the gas introduction port of the first gas pipe in the upper electrode is connected to the electrode plane of the upper electrode; and
a peripheral portion that surrounds the center portion and is provided with a plurality of gas holes,
the manufacturing method comprising:
forming a film by using a gas passed through the dispersion plate and the shower plate.
